(19) United States
(12) Patent Application Publication
(10) Pub. No.: US 2009/0156000 A1
(43) Pub. Date: Jun. 18, 2009

(54) METHOD OF MANUFACTURING SEMICONDUCTOR DEVICE

(76) Inventors: Yukiteru MATSUI, Yokohama-shi (JP); Atsushi Shigeta, Yokkaichi-shi (JP); Yoshikuni Tateyama, Hiratsuka-shi (JP); Takeshi Nishioka, Yokohama-shi (JP); Hiroyuki Yano, Yokohama-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/332,802

(22) Filed: Dec. 11, 2008

(30) Foreign Application Priority Data
Dec. 12, 2007 (JP) 2007-320962

(51) Int. Cl. H01L 21/283

(52) U.S. Cl. 438/666; 257/E21.159

(57) ABSTRACT

A method for manufacturing a semiconductor device is provided, which includes forming a coated film by coating a solution containing a solvent and an organic component above an insulating film located above a semiconductor substrate and having a recess, baking the coated film at a first temperature which does not accomplish cross-linking of the organic component to obtain an organic film precursor, polishing the organic film precursor using a first slurry containing first resin particles and a water-soluble polymer to planarize a surface of the organic film precursor, and polishing the organic film precursor where the surface is planarized using a second slurry containing second resin particles and a water-soluble polymer to leave the organic film precursor in the recess, thereby exposing the insulating film, an average particle diameter of the second resin particles being smaller than that of the first resin particles.

### CROSS-REFERENCE TO RELATED APPLICATIONS

This application is based upon and claims the benefit of priority from prior Japanese Patent Application No. 2007-320962, filed Dec. 12, 2007, the entire contents of which are incorporated herein by reference.

### BACKGROUND OF THE INVENTION

1. Field of the Invention

This invention relates to a method of manufacturing a semiconductor device.

2. Description of the Related Art

In the process for forming a dual damascene wiring structure of a semiconductor integrated circuit device, it is required to planarize an organic film employed as an underlying film. The planarization of the organic film has been conventionally employed for the via-first formation or so-called via-first in a dual damascene process wherein a trench pattern is formed after the formation of a hole pattern (via-hole pattern).

As described in US 2004/025822 for example, in the planarization of an organic film according to this process, a slurry containing resin particles is employed, for example. According to this process, the magnitude of dishing can be inhibited by regulating the size of resin particles to a range larger than the diameter of a hole.

Further, in viewpoint of the controllability of working and shaping, it is considered more advantageous to employ a hybrid-type interlayer insulating film structure. In the case of the hybrid dual damascene process, there has been mainly adopted a dual damascene process of the so-called trench mask-first, wherein a hard mask is worked so as to form a wiring trench.

In the working process of the trench mask-first, for the purpose of forming a wiring trench and a connecting hole by a hard mask consisting of a plurality of layers, there has been proposed, as seen in US 2005/0266355 for example, to form an underlying film, and then the surface of the underlying film is planarized by a CMP method. In this process, an organic film is formed on the hard mask having a wiring trench formed therein, by coating and then baking at a high temperature exceeding the cross-linking temperature thereof to form a film which is high in hardness. Subsequently, this hard organic film is removed by CMP using alumina particles, thereby inhibiting the magnitude of dishing.

However, this working process is accompanied with a problem that a deep scratch that may damage the hard mask may generate due to the alumina particles. The reason is that alumina particles are the highest in hardness of abrasive grains. Further, when alumina particles are left after the polishing of the organic film, they may act as an etching mask in a subsequent working process. As a result, an abnormal configuration may generate in the worked wirings, thus decreasing the yield of wirings.

### BRIEF SUMMARY OF THE INVENTION

A method for manufacturing a semiconductor device according to one aspect of the present invention comprises:

forming a coated film by coating a solution containing a solvent and an organic component above an insulating film located above a semiconductor substrate and having a recess;

baking the coated film at a first temperature which does not accomplish cross-linking of the organic component to obtain an organic film precursor;

polishing the organic film precursor using a first slurry containing first resin particles and a water-soluble polymer to planarize a surface of the organic film precursor; and

polishing the organic film precursor where the surface is planarized using a second slurry containing second resin particles and a water-soluble polymer to leave the organic film precursor in the recess, thereby exposing the insulating film, an average particle diameter of the second resin particles being smaller than that of the first resin particles.

A method for manufacturing a semiconductor device according to another aspect of the present invention comprises:

forming, through at least an organic insulating film, a first hard mask containing an inorganic material and a second hard mask containing an inorganic material, a third hard mask containing an inorganic material, above a semiconductor substrate;

forming a pattern of a wiring trench to be transcribed to the organic insulating film in the third hard mask, thereby exposing the second hard mask on a bottom of the pattern;

forming a coated film by applying a first solution containing a solvent and an organic component above the third hard mask where the pattern of the wiring trench is formed;

baking the coated film at a first temperature which does not accomplish cross-linking of the organic component to obtain an organic film precursor;

polishing the organic film precursor using a first slurry containing first resin particles having an average particle diameter ranging from 100-300 nm and a water-soluble polymer, thereby planarizing a surface of the organic film precursor;

polishing the organic film precursor where the surface is planarized using a second slurry containing second resin particles having an average particle diameter ranging from 10-70 nm and a water-soluble polymer, thereby leaving the organic film precursor in the wiring trench pattern and exposing the third hard mask;

applying a second solution containing a solvent and an organic component on the exposed surface of the third hard mask having the wiring trench pattern while leaving the organic film precursor in the wiring trench pattern, thereby forming an underlying film formed of an organic film;

forming an intermediate layer and a resist film successively above the underlying film; and

subjecting the resist film to patterning exposure.

### BRIEF DESCRIPTION OF THE SEVERAL VIEWS OF THE DRAWING

FIG. 1 is a cross-sectional view illustrating one step in the method of manufacturing a semiconductor device according to one embodiment;

FIG. 2 is a perspective view schematically illustrating a state of CMP (Chemical Mechanical Polishing) in one embodiment;

FIG. 3 is a cross-sectional view illustrating a step following the step shown in FIG. 1;

FIG. 4 is a cross-sectional view illustrating a step following the step shown in FIG. 3;

FIG. 5 is a cross-sectional view schematically illustrating the polishing mechanism in one embodiment;

FIG. 6 is a cross-sectional view illustrating a step following the step shown in FIG. 4;

FIG. 7 is a cross-sectional view illustrating a step following the step shown in FIG. 6;

FIG. 8 is a cross-sectional view illustrating a step following the step shown in FIG. 7;

FIG. 9 is a cross-sectional view illustrating a step following the step shown in FIG. 8;

FIG. 10 is a cross-sectional view illustrating a step following the step shown in FIG. 9;

FIG. 11 is a cross-sectional view illustrating a step following the step shown in FIG. 10;

FIG. 12 is a cross-sectional view illustrating a step following the step shown in FIG. 11; and

FIG. 13 is a cross-sectional view illustrating a step following the step shown in FIG. 12.

### DETAILED DESCRIPTION OF THE INVENTION

Embodiments of the present invention will be explained as follows with reference to drawings.

It should be appreciated that the present invention is not limited to the following embodiments but various modifications that can be practiced within the scope that does not depart from the spirit of the present invention.

In the manufacturing method of a semiconductor device according to one embodiment of the present invention, an organic film precursor is formed on an insulating film having a recess by solution containing an organic component and a solvent. More specifically, the recesses are formed creating a wiring trench pattern and the insulating film is a hard mask. After a coated film has been formed by applying the solution, a first baking is performed at a first temperature. This first temperature is limited to such that it is impossible to accomplish the cross-linking of the organic component and hence the organic film precursor is obtained by this first baking. Herein, the film where the cross-linking of the organic is not yet accomplished is referred to as an organic film precursor and the film where the cross-linking of the organic has been accomplished is referred to as an organic film.

The organic film precursor is chemically mechanically polished using a slurry containing resin particles and a water-soluble polymer, thereby exposing the insulating film. This chemical mechanical polishing is performed in two stages consisting of a first polishing and a second polishing. In the first polishing, the surface of the organic film precursor is planarized by resin particles having a relatively large average particle diameter and in the second polishing, the polishing thereof is performed using resin particles having a relatively small average particle diameter so as to expose the hard mask while keeping the planarity of the organic film precursor.

In the polishing of the organic film precursor, as shown in FIG. 1, an organic insulating film 4, a first hard mask 5, a second hard mask 6 and a third hard mask 7, each containing an inorganic material, are successively deposited on the semiconductor substrate 20 having semiconductor elements (not shown) formed therein at first. Then, wiring trench patterns 8a and 8b are formed as a recess in the third hard mask. In the embodiment shown in FIG. 1, the organic insulating film 4 is formed of a 2-ply structure consisting of a first organic insulating film 2 and a second organic insulating film 3. An etch-stopper film 1 is formed under the organic insulating film 4.

Although not shown in FIG. 1, an interlayer insulating film having a first wiring layer buried therein is interposed between the etch-stopper film 1 and the semiconductor substrate 20. With respect to the interlayer insulating film, it is possible to employ, for example, a silicon oxide film. The first wiring layer may be formed by burying, via a barrier layer, Cu in the silicon oxide film. The etch-stopper film 1 also acts to prevent the diffusion of this Cu and may be formed by depositing an SiN film for example.

The first organic insulating film 2 and the second insulating film 3 can be formed by depositing SiOC and PAE (polyaryl ether), respectively, by PE-CVD (Plasma Enhancement Chemical Vapor Deposition) method. With respect to the raw materials for the organic film, it is also possible to employ polyaryl ether (FLARE: trade name; Allied Signal Co., Ltd.; SiLK: trade name; Dow Chemicals Co., Ltd.), benzocyclobutene (Dow Chemicals Co., Ltd.), polyimide, etc. With respect to the film thickness of the first and the second insulating films 2 and 3, there is not any particular limitation and can be selected from the range of 50-400 nm.

With respect to the raw materials for the organic film to be formed by CVD method, there have been known various materials such as Choral (trade name; Nobelas Co., Ltd.), Aurora (trade name; ASM Co., Ltd.), Black Diamond (trade name; Applied Materials Co., Ltd.), etc. With respect to the raw materials for the organic film to be formed by coating method, there have been known various materials such as methylsilsesquioxane, etc.

Then, a silane-based SiO₂ film is formed as a first hard mask 5 on the organic insulating film 4 which is constituted by the first and the second organic insulating films 2 and 3 by CVD method or PVD (Physical Vapor Deposition) method. As the second hard mask 6, it is possible to employ, for example, a SiN film. As the third hard mask 7, a SiO₂ film may be formed using, for example, TEOS (tetraethoxy silane). With respect to the film thickness of each of the first, the second and the third masks, it may be about 145 nm, about 50 nm and about 50 nm, respectively. Incidentally, these first, second and third hard masks 5, 6 and 7 may be formed by any of these materials. Further, these hard masks may be formed by silicon carbide film.

After a resist pattern (not shown) is formed on the third hard mask 7, this third hard mask 7 is subjected to dry etching by C₄F₈/CO/Ar gas, thereby forming the wiring trench patterns 8a and 8b both constituted by recesses in the third hard mask 7 as shown in FIG. 1. The width of the wiring trench pattern 8a may be 3000 nm and the width of the wiring trench pattern 8b may be 90 nm.

As shown in FIG. 1, an organic film precursor 9 is formed on the third hard mask 7 having the wiring trench patterns 8a and 8b formed therein. This organic film precursor 9 is permitted to contact, at the bottom thereof, with the second hard mask 6 made of SiN. On the occasion of forming the organic film precursor 9, a resist for i-ray containing novolac resin as a major component (IX370G; JSR Co., Ltd.) is coated to form a coated film having a film thickness of 0.1-3 μm or so. The resist for i-ray may be dissolved in a solvent such as ethyl lactate and 3-ethoxy-ethyl propionate for the formation of a coated film. The organic film precursor may be formed by a resin for the anti-reflection film of ArF excimer laser (ODL-50; JSR Co., Ltd.).

The organic film comprising novolac resin as a major component is more preferable than an organic film comprising, for example, cyclohexanone as a major component in the respect that the planarizing of film can be easily accomplished. Further, the organic film comprising novolac resin as a major component is stronger in adhesive force to the third hard mask 7 and the peeling thereof at the time of CMP is relatively limited as compared with the organic film comprising cyclohexanone as a major component.

The hardness of the film containing an organic component such as novolac resin, etc. can be controlled by the baking temperature thereof. Generally, a film containing an organic component is featured such that when the baking temperature is increased, the cross-linking reaction of polymer included therein is started and when the baking temperature is increased to exceed the cross-linking terminating temperature, the cross-linking reaction of the polymer is accomplished, obtaining a film having a very high hardness. In the case of novolac resin, the cross-linking reaction thereof is started at a temperature of nearly 150° C. and can be accomplished at a temperature of nearly 280° C. For example, when the baking temperature is 300° C., an average hardness of the organic film to be obtained would become 0.5 GPa or so. An organic film having an average hardness of not less than 0.5 GPa or so cannot be polished by resin particles.

Therefore, in the embodiments of the present invention, the first temperature at which the first baking is performed is required to be such that the cross-linking reaction of a polymer is not yet accomplished. For example, in the case of novolac resin, the first temperature should preferably be confined to the range of 90-160° C. As long as the first temperature is limited within this range, it becomes possible to prevent the accomplishment of cross-linking of polymer and hence to obtain an organic film precursor which is suited for the polishing using resin particles.

As shown in FIG. 1, a step portion 10 reflecting the wiring trench pattern 8a can be generated on the surface of the organic film precursor 9 to be obtained from the first baking performed at the aforementioned first temperature. In this embodiment, a redundant portion of the organic film precursor 9 is removed by polishing using CMP, thereby burying the organic film precursor 9 in the wiring trench patterns 8a and 8b.

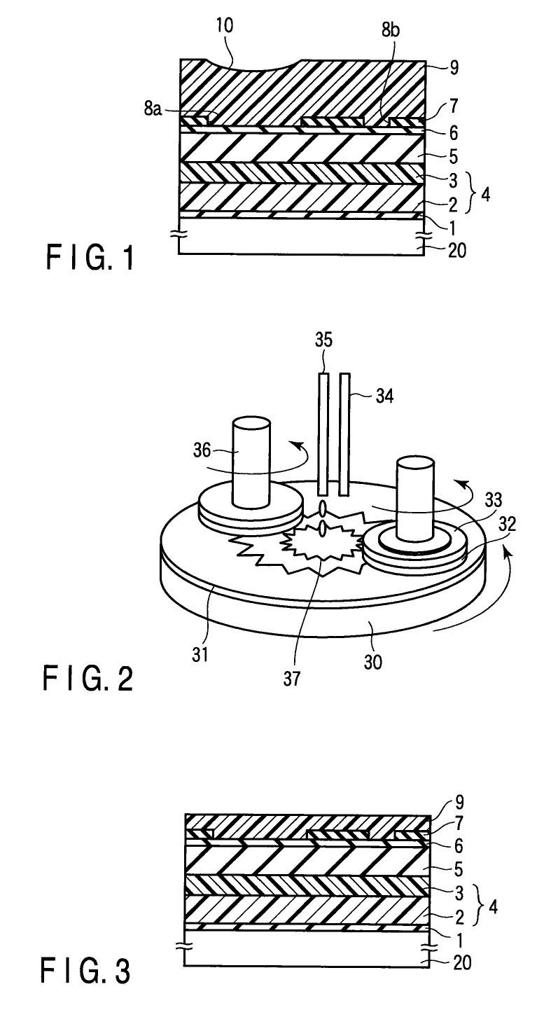

The polishing and elimination of the organic film precursor 9 is performed by CMP using a slurry containing resin particles and a water-soluble polymer. Specifically, a polishing pad made of, for example, IC1000/Suba 400 (Nitta Haas Co., Ltd.) is employed and, as shown in FIG. 2, while rotating a turntable 30 having a polishing pad 31 attached thereon at a speed of 10-70 rpm, a top ring 33 holding a semiconductor substrate 32 is forced to contact with the polishing pad 31 at a polishing load of 10-70 gf/cm². The rotational speed of the top ring 33 may be set to 20-50 rpm and a slurry 37 is fed from a slurry feed nozzle 35 to the polishing pad 31 at a flow rate of 30-1000 cc/min. Incidentally, FIG. 2 also shows a water feed nozzle 34 and a dresser 36.

First of all, using the first slurry, the first polishing is performed to reduce the film thickness of the organic film precursor 9 while planarizing the surface of the organic film precursor 9. As described below, a slurry containing resin particles having a smaller average particle diameter is used in the second polishing. Because of this, the polishing speed decreases in the second polishing. If the film thickness of the organic film precursor 9 to be removed in the second polishing is sufficiently small, the influence to be affected by the decrease of polishing speed can be minimized. Therefore, it is desirable that the distance between the third hard mask 7 and the surface of the organic film precursor 9 can be reduced as much as possible by the first polishing.

The film thickness of the organic film precursor 9 after the first polishing can be controlled by the adjustment of the polishing time for example. In this case, a solid film of the organic film precursor 9 is polished in advance at predetermined conditions to determine the polishing speed of the organic film precursor 9 for controlling the film thickness of the organic film precursor. Alternatively, a table torque current is monitored during the first polishing, thereby making it possible to accurately control the residual film thickness of the organic film precursor 9. Namely, the moment of planarization is detected based on the change of the monitored waveform and then over-polishing is performed for a pre-set period of time, thereby accomplishing the first polishing.

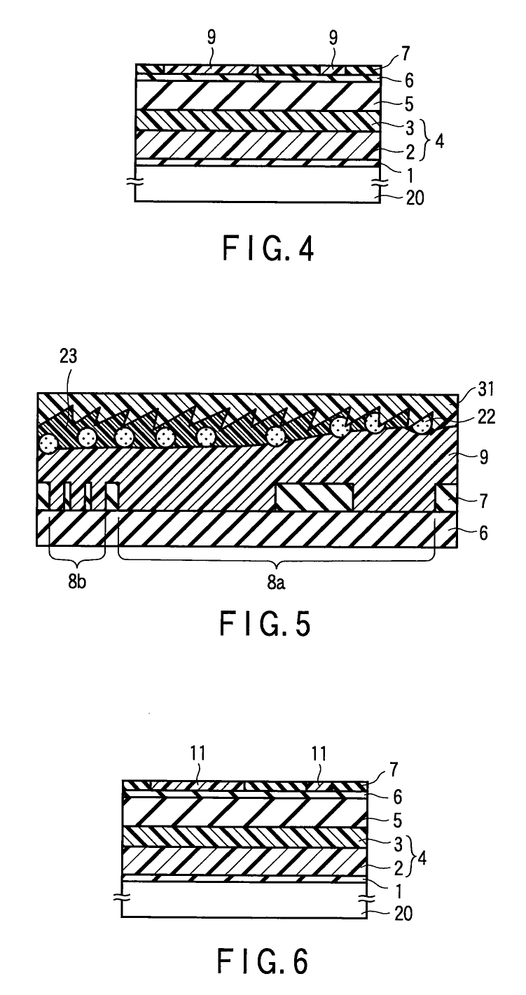

At the moment when the first polishing is accomplished, the first slurry is switched to the second slurry to initiate the second polishing. The second slurry may be formulated in the same manner as the first slurry except that the average particle diameter of the resin particles contained therein is smaller than that of the resin particles contained in the first slurry. By the execution of this second polishing, the third hard mask is exposed as shown in FIG. 4.

The resin particles may be particles of a resin selected from the group consisting of acrylic resin such as PMMA (polymethyl methacrylate), PST (polystyrene)-based resin, styrene/acryl copolymer resin, urea resin, melamine resin, polyacetal resin and polycarbonate resin. The resin particles may be constituted by a composite resin. Especially, in viewpoints of hardness and elasticity which are suited for the CMP of the organic film precursor, PMMA, PST or styrene/acryl copolymer resin is more preferable.

The resin particles may be formed of a cross-linked structure. When the resin particles are formed of a cross-linked structure, it becomes possible to enhance the hardness and elasticity of the resin particles, thereby making the resin particles more suitable for the CMP of the organic film precursor. The resin particles having a cross-linking structure can be manufactured by using, as a raw material thereof, a polyfunctional monomer. This polyfunctional monomer is a monomer having two or more polymeric unsaturated bonds, examples of which including, for example, divinyl aromatic compounds, polyvalent (metha)acrylate, etc.

At least one selected from anionic functional group, cationic functional group, amphoteric functional group, and nonionic functional group may be introduced on the surface of these resin particles. With respect to the anionic functional group, it is possible to employ carboxylic acid type, sulfonic acid type, sulfate ester type, or phosphate ester type functional group. With respect to the cationic functional group, it is possible to employ, for example, amine salt type or quaternary ammonium salt type functional group. With respect to the amphoteric functional group, it is possible to employ, for example, alkanolamide type, carboxy betaine type or glycine type functional group. With respect to the nonionic functional group, it is possible to employ, for example, ether type or ester type functional group. Because of easiness in the manufacture of resin particles, carboxyl group is especially preferable.

In order to stably disperse the resin particles in a solvent, the absolute value of ζ potential should preferably be higher than a prescribed value. More specifically, the absolute value of ζ potential should preferably be about 20 mV or more. This magnitude of ζ potential can be achieved by setting the content of the functional group to around 0.05 mol/L or more. Under some circumstances, two or more kinds of functional groups may be concurrently existed. When these functional groups are existed on the surface of resin particles, the dispersibility of the resin particles can be enhanced due to the electric repulsion force among the resin particles without necessitating the addition of a surfactant.

For example, in the case of the resin particles having, as a functional group, carboxyl group (COOH) on the surface thereof, the carboxyl group is dissociated in a slurry as represented by: COOH→COO⁻+H⁺, thus electrifying the surface of resin particles with negative electricity. Because of this, the aggregation among the resin particles can be prevented due to the electric repulsion force, thereby making it possible to enhance the dispersibility of the resin particles and to prolong the life of the slurry.

Cross-linked PMMA particles having carboxyl group (COOH) on the surface thereof can be synthesized according to the following procedures. First of all, methyl methacrylate, methacrylic acid, divinyl benzene, ammonium lauryl sulfate and ammonium persulfate are introduced, together with a sufficient amount of ion-exchange water, into a flask. The solution in the flask is heated up to 70-80° C. with stirring in a nitrogen gas atmosphere, thereby allowing polymerization to take place for 6-8 hours. As a result, it is possible to obtain PMMA particles having carboxyl group on the surface thereof. By suitably modifying the manufacturing conditions such as the quantity of monomer to be used as a raw material, the reaction temperature and time, etc., the average particle diameter of the resin particles can be controlled within a prescribed range.

The average particle diameter of the resin particles can be determined by, for example, TEM observation, SEM observation or the measurement of particle size distribution.

The average particle diameter of the second resin particles to be contained in the second slurry is smaller than the average particle diameter of the first resin particles to be contained in the first slurry. More preferably, the average particle diameter of the first resin particles should preferably be confined within the range of 100-300 nm and the average particle diameter of the second resin particles should preferably be confined within the range of 10-70 nm. When the recesses to be filled with the organic film precursor 9 is formed so as to constitute a wiring trench pattern, the average particle diameter of resin particles to be contained in each of these slurries should preferably be confined within the aforementioned ranges.

In the first polishing to be performed using the first slurry, the organic film precursor 9 is polished away at a sufficiently high speed so as to planarize the surface of the organic film precursor 9. As long as the average particle diameter of the resin particles to be used as abrasive gains is 100 nm or more, it is possible to derive the planarization effects thereof. If the average particle diameter of the resin particles is too large, the dispersion of the resin particles in the slurry may be deteriorated and, at the same time, the generation of scratches on the surface of film after the polishing thereof may be increased. In order to obviate these problems, the upper limit of the average particle diameter of the resin particles should preferably be confined to 300 nm or less.

On the other hand, in the second polishing using the second slurry, it is demanded to remove the organic film precursor 9 without generating dishing and to expose the surface of the third hard mask. As long as the average particle diameter of the resin particles is 70 nm or less, it is possible to inhibit the generation of dishing. However, when the resin particles are excessively small, it would be impossible to remove the organic film precursor 9 and these small resin particles may generate secondary aggregation. As long as the average particle diameter of the resin particles is 10 nm or more, it is possible to polish the organic film precursor 9 at a practical speed while inhibiting the generation of the secondary aggregation.

In any of the first and the second slurries, the resin particles should preferably be dispersed in the slurry so as to confine the concentration of the resin particles in the slurry to about 0.01-10 wt %. If the concentration of the resin particles is less than 0.01 wt %, it may become difficult to polish the organic film precursor at a sufficiently high speed. On the other hand, if the concentration of the resin particles is higher than 10 wt %, the generation of dishing on the surface of organic film precursor may be enlarged. More preferably, the concentration of the resin particles should be confined to 0.1-5 wt %, most preferably 0.3-3 wt %.

In this embodiment, a slurry containing a water-soluble polymer in addition to the aforementioned resin particles is employed. This is related to the fact that the recesses to be filled with an organic film precursor are formed to constitute a wiring trench pattern.

The dimension of the wiring trench pattern may be generally confined to several micrometers and hence larger than the size of the resin particles. Accordingly, resin particles may enter into the wiring trench pattern to enlarge the dishing on the occasion of planarizing the organic film precursor that has been formed on the insulating film having the wiring trench pattern. As a result, it may become impossible to secure the surface planarity, thus giving rise to the occurrence of focus error in the following lithography process for forming a pattern of holes.

It may be conceivable to increase the hardness of the organic film precursor to be polished in order to inhibit the magnitude of dishing. However, since the resin particles to be used in the polishing in this embodiment are very soft and relatively poor in polishing action, they cannot be used for polishing a film of high hardness. Since the temperature of the first baking to be performed prior to the CMP is regulated to such a low temperature that cannot accomplish the cross-linking of the organic component, a high-temperature baking cannot be adopted herein.

In this embodiment, the inhibition of the dishing can be made possible through the incorporation of a water-soluble polymer in the slurry in addition to the resin particles. This water-soluble polymer adsorbs onto the surface of the organic film precursor to be polished and hence is effective in protecting the organic film precursor from the action of the resin particles. The mechanism about the effects of this water-soluble polymer will be discussed hereinafter.

Examples of the water-soluble polymer include, for example, celluloses such as methyl cellulose, methyl hydroxyethyl cellulose, methyl hydroxypropyl cellulose, hydroxyethyl cellulose, hydroxypropyl cellulose, carboxymethyl cellulose, carboxyethyl cellulose, carboxymethyl hydroxyethyl cellulose, etc.; polysaccharides such as chitosan, etc.; polyethylene glycol; polyethylene imine; polyvinylpyrrolidone; polyvinyl alcohol; polyacrylic acid and salts thereof; polyacryl amide; polyethylene oxide; etc. These water-soluble polymers may be employed singly or in combination of two or more kinds.

Among these water-soluble polymers, polyvinyl alcohol and polyvinylpyrrolidone are more preferable in terms of realizing excellent planarization.

Preferably, the water-soluble polymer should be selected from those having an average molecular weight of 500-1,000,000. If the average molecular weight of the water-soluble polymer is less than 500, it may be impossible to secure a sufficient interaction thereof to the organic film precursor to be polished and the effects of the water-soluble polymer to protect the organic film precursor would be reduced, thereby making it difficult to inhibit the dishing. On the other hand, if the average molecular weight of the water-soluble polymer is larger than 1,000,000, the effects of adsorption thereof to the organic film precursor would become excessive, thus possibly resulting in the decrease of polishing rate. Additionally, the viscosity of the slurry may become too high, thus possibly making it difficult to feed the slurry. Therefore, the average molecular weight of the water-soluble polymer should preferably be confined to the range of 1,000-500,000, more preferably 5,000-300,000.

With respect to the concentration of the water-soluble polymer in the slurry, it should preferably be confined to the range of 0.001-10 wt %. If the concentration of the water-soluble polymer is less than 0.001 wt %, it would become impossible to enable the water-soluble polymer to act as a lubricant between the polishing pad and a semiconductor substrate, more likely giving rise to the peeling of film. Moreover, it may become difficult to inhibit the dishing. On the other hand, if the concentration of the water-soluble polymer is higher than 10 wt %, the water-soluble polymer may excessively adsorb onto the organic film precursor, thus possibly extremely decreasing the polishing rate. More preferably, the concentration of the water-soluble polymer should be confined to 0.01-1 wt %, most preferably 0.05-0.5 wt %.

Since the polishing is performed using a slurry containing a water-soluble polymer and resin particles, the dishing of the organic film precursor 9 to the wiring trench patterns 8a and 8b can be suppressed to 20 nm or less, thus remarkably improving the planarity. The reason for this can be attributed to the existence of the water-soluble polymer in the slurry as explained below.

In the case where the CMP of the organic film precursor is performed using a slurry containing the resin particles without the inclusion of the water-soluble polymer, the polishing goes on while peeling the organic film precursor due to the effects of high friction. Whereas, as shown in FIG. 5, in the case of the slurry containing not only a resin particles 22 but also a water-soluble polymer 23, the water-soluble polymer 23 acts like a lubricating oil between a wafer and a polishing pad 31, thereby alleviating the friction and hence realizing a polishing mechanism wherein the organic film precursor 9 can be gradually removed. In addition to this, the water-soluble polymer 23 adsorbs onto the surface of the organic film precursor 9, thereby protecting the surface of the organic film precursor 9 from the action of the resin particles 22. As a result, due to the employment of the slurry comprising the water-soluble polymer 23 in addition to the resin particles 22, it is now possible to secure the planarity and, at the same time, to inhibit the generation of scratches owing to the softness of the resin particles 22.

Furthermore, since the material to be employed as a abrasive grain is formed of resin particles having almost the same characteristics as those of the organic film precursor, even if the resin particles are left behind after the CMP, there is no possibility of the resin particles being turned into an etching mask in the subsequent working processes as seen in the case of alumina particles. For this reason, it is possible to minimize the risk resulting from the residual particles. As a result, it is possible to minimize the focus error in the lithography for forming via-holes in a subsequent step, thus making it possible to remarkably enhance the yield.

Incidentally, when the polishing is performed using a slurry comprising only a water-soluble polymer, the polishing rate would become very slow even though it may be possible to confine the dishing to 20 nm or less due to the mechanism as described above. Therefore, in order to secure the practical polishing rate on the occasion of embedding the organic film precursor in the wiring trench pattern constituted by recesses, it is needed to employ the water-soluble polymer together with the resin particles.

The slurry of this embodiment can be obtained by incorporating the aforementioned resin particles in water together with a water-soluble polymer. As the kind of water, it is possible to employ, for example, ion-exchange water and pure water.

If required, additives such as an oxidizing agent, an organic acid and a surfactant may be contained in the slurry at an amount which is generally employed.

The pH of the slurry to be used in this embodiment of the present invention should preferably be confined to the range of 2 to 8. If the pH of the slurry is less than 2, the functional group such as COOH cannot be easily dissociated, thus possibly resulting in the deterioration of dispersibility of the resin particles. On the other hand, if the pH of the slurry is more than 8, chemical damages to the organic film precursor such as a resist film would become prominent, more likely resulting in the increase of dishing.

By suitably incorporating a pH adjustor, the pH of the slurry can be adjusted to the aforementioned range. As the pH adjustor, it is possible to employ, for example, nitric acid, phosphoric acid, hydrochloric acid, sulfuric acid, citric acid, etc.

Since the first polishing is performed using the first slurry containing resin particles and a water-soluble polymer, it is possible to achieve the planarization of the organic film precursor at a sufficiently high speed while avoiding the problem of enlarging the dishing. Further, since the second polishing is performed using the second slurry containing resin particles having a relatively small average particle diameter and a water-soluble polymer, it is possible to inhibit the regeneration of dishing on the surface of the organic film precursor. Moreover, even in the second polishing, it is possible to polish the organic film precursor at a practical speed.

With respect to the concentration of the resin particles and the water-soluble polymer in the second slurry, it may not necessarily be the same as that of the first slurry as long as the requirement of the average particle diameter of the resin particles is satisfied as described above. For example, the quantity of the resin particles to be contained in the second slurry may be smaller than that in the first slurry. Alternatively, the quantity of the water-soluble polymer to be contained in the second slurry may be larger than that in the first slurry. In either cases, the effect of securing a large polishing rate while completely inhibiting the generation of dishing may not be diminished at all.

As shown in FIG. 4, the organic film precursor 9 is left remain in the wiring trench patterns 8a and 8b and the third hard mask 7 is exposed. Further, the dishing on the surface of the organic film precursor 9 after the polishing thereof can be inhibited to 20 nm or less.

Under the condition where the organic film precursor 9 is left remain in the wiring trench patterns 8a and 8b, the second baking of the organic film precursor 9 should preferably be performed at a second temperature which is higher than the first temperature. As a result of this second baking, the solvent contained in the organic film precursor 9 can be removed and, at the same time, the cross-linking reaction of the organic film precursor 9 can be accomplished, thus obtaining an organic film (a first organic film) 11 as shown in FIG. 6. In a case where novolac resin is employed by dissolving it in ethyl lactate or 3-ethoxypropyl ethyl lactate to be used as a solvent for instance, the second temperature may be confined to the range of about 250-400° C. As long as the second temperature is confined within this range, it is possible to reliably remove the solvent without bringing about the decomposition of the novolac resin.

In FIG. 6, the organic film 11 buried in the wiring trench patterns 8a and 8b has been subjected to the second baking at a second temperature to remove the solvent from these wiring trench patterns. Due to the non-existence of the solvent in any substantial extent, even if a coated film is deposited on the organic film 11 in a subsequent step, the planarity of the coated film would not be spoiled. Incidentally, it is difficult to form a coated film having a planar surface on the organic film precursor containing a residual solvent. Namely, the residual solvent left in the interior of planarized organic film precursor may react with a solvent contained in the coated film, thereby negating the effect of planarization to be derived from the planarized organic film precursor.

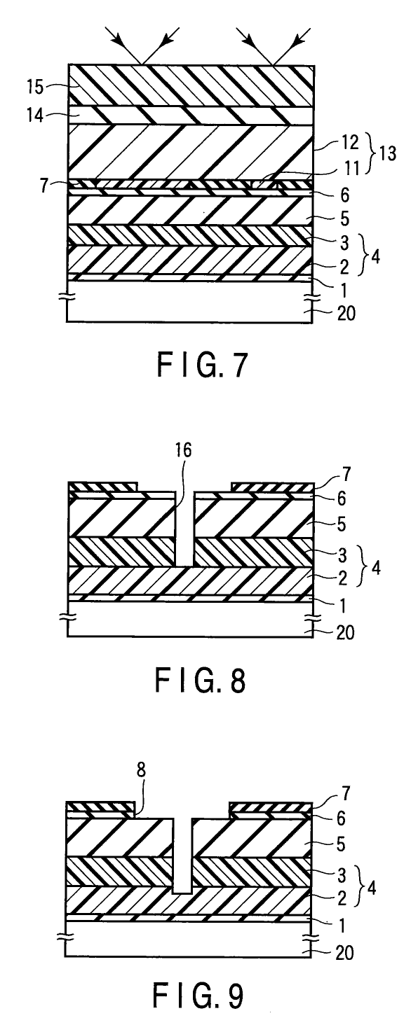

Then, IX370G is coated again to form a second organic film 12 on the first organic film 11, thus obtaining an underlying film 13 constituted by the first organic film 11 and the second organic film 12. Then, as shown in FIG. 7, an SOG (Spin On Glass) film as the intermediate layer 14 and a resist film 15 are successively deposited. Herein, the second organic film 12 may be deposited at a thickness of 300 nm or so. Further, the thickness of the intermediate layer 14 and of the resist film 15 may be about 45 nm and about 200 nm, respectively.

It is preferable to bake the underlying film 13 at a temperature of 250-400° C. or so (a third baking) after the deposition of a coated film to be used as the second organic film 12 on the first organic film 11 and prior to the formation of an intermediate layer 14 to be deposited thereon. Due to this third baking, it is possible to enhance the etching resistance of the underlying film 13 without bringing about the decomposition of the organic components contained in the first and the second organic films 11 and 12.

Since the surface of the underlying film 13 is planar, the surface of the resist film 15 formed thereon would become also planar. Due to the planarity of the surface of the resist film 15, it is possible to make approximately constant the focus error irrespective of line width on the occasion of performing the patterning exposure of the resist film 15 as shown in FIG. 7. As a result, it is now possible to remarkably improve the non-uniformity in dimension of the pattern and, furthermore, to remarkably enhance the yield.

The resist film 15 that has been subjected to the exposure is then developed by a developing solution to obtain a resist pattern (not shown). Then, using this resist pattern as an etching mask, the intermediate layer 14 is worked by CHF₃/O₂ gas. Furthermore, the underlying film 13 is worked by NH₃/O₂/CH₄ gas and then the resist pattern is peeled off by O₂ ashing.

Using the patterned intermediate layer 14 and the patterned underlying film 13 as a mask, a connecting hole (via-hole) is created in the second hard mask 6 as well as in the first hard mask 5 by dry-etching. As the etching gas to be used in this case, it is possible to employ CHF₃/Ar/O₂ gas. During the working of the first hard mask 5, the intermediate layer 14 is removed. Furthermore, the resultant body is subjected to dry etching using NH₃ gas to form connecting holes 16 in the second organic insulating film 3 as shown in FIG. 8. In this FIG. 8, only the region of the wiring trench pattern 8a is depicted selecting from the wiring trench patterns 8a and 8b which are shown in FIG. 1. In the following FIGS. also, only the region of the wiring trench pattern 8a will be illustrated. Incidentally, the underlying film 13 is removed on the occasion of working the second organic insulating film 13.

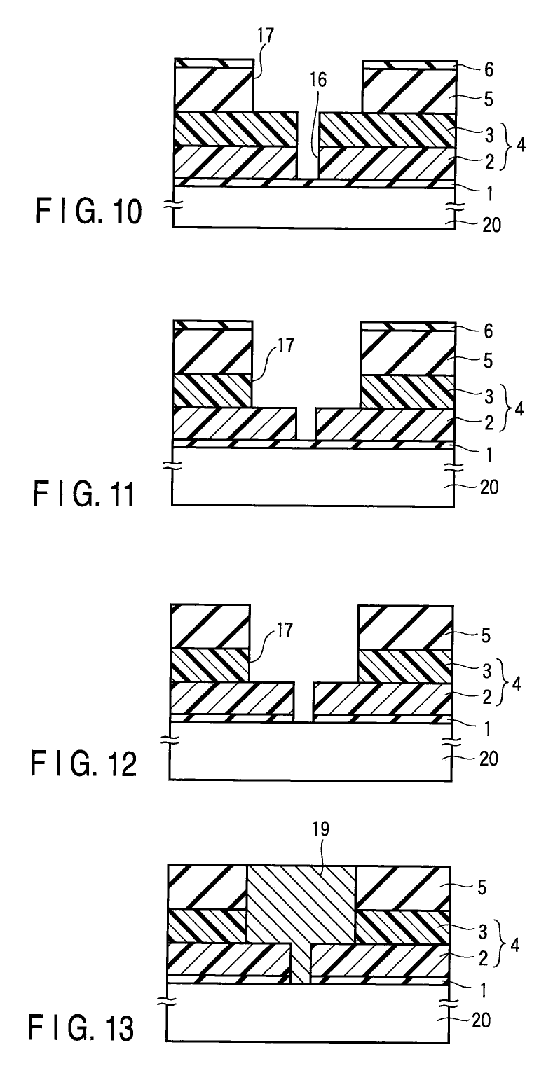

Then, by CH₂F₂/CF₄/Ar/O₂ gas, the resultant body is dry-etched to form a wiring trench pattern 8 in the second hard mask 6 as shown in FIG. 9. As shown in FIG. 9, at this moment, the connecting hole 6 is dug down to an intermediate portion of the first organic insulating film 2. Furthermore, by C₅F₈/Ar/O₂ gas, the third hard mask 7 is removed and, at the same time, a wiring trench 17 is formed in the first hard mask 5 as shown in FIG. 10. At this moment, the connecting hole 16 is dug down to reach the etch-stopper film 1. By this two-stage working process as explained above, the connecting hole 16 can be formed in the first organic insulating film 2. This working process is advantageous in the respect that the connecting hole 16 can be reliably formed so as to pierce through the first organic insulating film 2, thus exhibiting the advantage of a triple-hard mask process.

Then, by dry etching using NH₃ gas, a wiring trench 17 is formed in the second organic insulating film 3 as shown in FIG. 11. Finally, by CH₂F₂/CF₄/Ar/O₂ gas, the second hard mask 6 is removed as shown in FIG. 12. At this moment, the etch-stopper film 1 existing at the bottom portion of the connecting hole 16 is also removed.

Subsequently, a barrier layer (not shown) is formed on the inner surface of the recesses including the connecting hole 16 and the wiring trench 17 and then the recesses are filled with Cu. Then, redundant portions of Cu film and barrier layer which are deposited on a silicon oxide film constituting the first hard mask 5 are removed. As a result, a Cu damascene wiring can be formed in the recesses as shown in FIG. 13, thus creating a hybrid dual damascene wiring 19.

In this embodiment, the organic film precursor 9 is removed in two stages of polishing on the occasion of forming a multi-layer wherein the second organic film 12 is deposited on the first organic film 11. After the organic film precursor 9 is subjected to a first baking at a first temperature, the organic film precursor 9 is planarized at a sufficiently high speed in the first polishing. Thereafter, in the second polishing, the third hard mask is exposed without generating dishing. In this manner, it is possible to bury the organic film precursor 9 having a planar surface in the wiring trench patterns 8a and 8b.

Moreover, since the solvent existing in the organic film precursor can be removed as the organic film precursor 9 is baked at the second temperature after the CMP, there is no possibility that the planarity of the surface of organic film precursor can be spoiled by a coated film to be formed thereon. Therefore, the focus error that may occur on the occasion of exposure can be inhibited to 20 nm or less and hence it is now possible to minimize the non-uniformity in dimension of the pattern and, furthermore, to remarkably enhance the yield.

Next, embodiments of the present invention will be explained with reference to specific examples. First of all, slurries having the following features were prepared.

(Slurry 1)

92 parts by weight of styrene, 4 parts by weight of methacrylic acid, 4 parts by weight of hydroxyethyl acrylate, 0.1 part by weight of ammonium lauryl sulfate, 0.5 part by weight of ammonium persulfate and 400 parts by weight of ion-exchange water were introduced into a 2 L flask. The resultant solution in the flask was heated up to 70° C. with stirring in a nitrogen gas atmosphere, thereby allowing polymerization to take place for 6 hours. As a result, it was possible to obtain PST particles having carboxyl group on the surface thereof and an average particle diameter of 200 nm.

Then, the PST particles were dispersed in pure water at a concentration of 0.83 wt % to obtain a dispersion to which 0.16 wt % of polyvinyl alcohol having a molecular weight of 17600 was added at a content of 0.16 wt %, thus obtaining the Slurry 1.

(Slurry 2)

77 parts by weight of styrene, 3 parts by weight of acrylic acid, 20 parts by weight of divinyl benzene, 2.0 parts by weight of ammonium dodecylbenzene sulfonate, 1.0 part by weight of ammonium persulfate and 400 parts by weight of ion-exchange water were introduced into a 2 L flask. The resultant solution in the flask was heated up to 70° C. with stirring in a nitrogen gas atmosphere, thereby allowing polymerization to take place for 6 hours. As a result, it was possible to obtain cross-linked PST particles having carboxyl group on the surface thereof and an average particle diameter of 50 nm.

Then, the cross-linked PST particles were dispersed in pure water at a concentration of 0.66 wt % to obtain a dispersion and then 0.33 wt % of polyvinyl alcohol having a molecular weight of 17600 was added, as a water soluble polymer, to the dispersion to obtain Slurry 2.

(Slurry 3)

A slurry 3 was obtained in the same manner as in the case of the slurry 1 except that the average particle diameter of the PST particles was changed to 100 nm.

(Slurry 4)

A slurry 4 was obtained in the same manner as in the case of the slurry 1 except that the average particle diameter of the PST particles was changed to 300 nm.

(Slurry 5)

A slurry 5 was obtained in the same manner as in the case of the slurry 2 except that the average particle diameter of the PST particles was changed to 30 nm.

(Slurry 6)

A slurry 6 was obtained in the same manner as in the case of the slurry 2 except that the average particle diameter of the PST particles was changed to 70 nm.

Using the slurries obtained as describe above, the polishing of the organic film precursor was performed by the method according to the embodiments of the present invention.

First of all, an organic film precursor 9 was formed on the third hard mask 7 provided with wiring trench patterns 8a and 8b as shown in FIG. 1. Then, the first baking was applied to the organic film precursor 9 at 130° C. The surface of the organic film precursor 9 was accompanied with step portions having a height of around 50 nm before the polishing of the organic film precursor 9. Then, using the slurry 1, the organic film precursor 9 was removed through polishing, thereby planarizing the surface of organic film precursor 9 as shown in FIG. 3 (a first polishing). After the first polishing, the slurry 2 was used to polish and remove the organic film precursor 9, thereby exposing the third hard mask 7 as shown in FIG. 4 (a second polishing).

Due to the first polishing, the surface of the organic film precursor 9 was planarized taking 90 seconds of polishing. Since the average particle diameter of the resin particles contained in the slurry 1 employed herein was as large as 200 nm, it was possible to secure a sufficiently high polishing speed.

Due to 90 seconds of the second polishing using the slurry 2, the third hard mask 7 was exposed leaving the organic film precursor 9 in the wiring trench pattern 8. Since the average particle diameter of the resin particles contained in the second slurry 2 was as small as 50 nm, it was possible to prevent the planarity of the surface of organic film precursor 9 from being spoiled. The planarity of the surface of organic film precursor 9 after the second polishing was confined to 20 nm or less.

Thereafter, the second baking was performed at a temperature of 300° C. to bury the first organic film 11 in the third hard mask 7 as shown in FIG. 6. Further, as shown in FIG. 7, a second organic film 12, an intermediate layer 14 and a resist film 15 were successively deposited on the third hard mask 7. Then, the resist film 15 was subjected to exposure to determine the focus error. As a result, the focus error was found limited to 20 nm or less.

After finishing the patterning of the resist film 15, a Cu dual damascene wiring was formed according to the method illustrated with reference to FIGS. 8-13 and the yield of the wiring was measured by a prober, finding a yield of not less than 80%.

Incidentally, even when the slurry 3 and the slurry 4 were employed in the first polishing, the planarization of the organic film precursor 9 was accomplished within 90 seconds.

When the slurry 5 and the slurry 6 were employed in the second polishing, the third hard mask 7 was enabled to expose within 90 seconds of polishing and the surface planarity of the organic film precursor 9 was confined to 20 nm or less.

For the purpose of comparison, the organic film precursor 9 was removed through the polishing thereof using only the slurry 1, thereby planarizing the surface of organic film precursor 9 and then the polishing was continued to expose the third hard mask 7 (Comparative Example 1). As a result, the surface of organic film precursor 9 having the third hard mask 7 buried therein was accompanied with step portions having a height of as large as 40 nm. These step portions would inevitably become a cause for the focus error.

Further, the organic film precursor 9 was polished using only the slurry 2 to planarize the surface of organic film precursor 9 and then the polishing was continued to expose the third hard mask 7 (Comparative Example 2). In this case, it took as long as 240 seconds for exposing the third hard mask 7. Since the average particle diameter of the resin particles contained in the slurry 2 was as small as 50 nm, the speed for planarizing the recesses/projections of the organic film precursor 9 was extremely low and therefore it was impossible to polish the organic film precursor 9 at a practical speed. This would lead to the deterioration of productivity.

As clearly seen from the results described above, due to the employment of the method of this embodiment, it was possible to bury an organic film precursor in a wiring trench pattern for forming an organic film which was minimal in defectives and excellent in surface planarity. Additionally, it was possible to polish the organic film precursor at a practical speed. As a solvent contained in the organic film precursor is removed, an organic film having a planar surface can be created as an underlying film, thereby making it possible to improve the planarity of a resist film to be used in a patterning exposure.

According to embodiments of the present invention, it is possible to provide a method of manufacturing a semiconductor device, which is capable of planarizing the organic film while minimizing the generation of defectives and of forming a dual damascene wiring at a high yield.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A method for manufacturing a semiconductor device comprising:
forming a coated film by coating a solution containing a solvent and an organic component above an insulating film located above a semiconductor substrate and having a recess;
baking the coated film at a first temperature which does not accomplish cross-linking of the organic component to obtain an organic film precursor;
polishing the organic film precursor using a first slurry containing first resin particles and a water-soluble polymer to planarize a surface of the organic film precursor; and
polishing the organic film precursor where the surface is planarized using a second slurry containing second resin particles and a water-soluble polymer to leave the organic film precursor in the recess, thereby exposing the insulating film, an average particle diameter of the second resin particles being smaller than that of the first resin particles.

2. The method according to claim 1, further comprising
baking the organic film precursor left in the recess at a second temperature which is higher than the first temperature to remove the solvent to obtain a first organic film embedded in the recess; and
forming a second organic film by coating on the insulating film where the first organic film is embedded, thereby obtaining an underlying film.

3. The method according to claim 2, further comprising
forming an intermediate layer and a resist film successively above the underlying film; and
subjecting the resist film to patterning exposure.

4. The method according to claim 3, wherein the insulating film is a third hard mask containing an inorganic material and formed, through at least an organic insulating film, a first hard mask containing an inorganic material and a second hard mask containing an inorganic material, above the semiconductor substrate; the recess is a pattern of a wiring trench to be transcribed to the organic insulating film and is formed in the third hard mask, the second hard mask being exposed at a bottom of the recess.

5. The method according to claim 4, further comprising
forming a pattern of a hole in the resist film;
transcribing the pattern of the hole to the organic insulating film to form a hole in the organic insulating film and, at the same time, removing the underlying film to create the pattern of the wiring trench;
transcribing the pattern of the wiring trench to the organic insulating film to form a wiring trench communicating with the hole; and
forming a dual damascene wiring in the hole and in the wiring trench.

6. The method according to claim 3, further comprising
baking the underlying film at a temperature of 250-400° C. prior to forming the intermediate layer.

7. The method according to claim 1, wherein an average particle diameter of the first resin particles is confined to 100-300 nm and an average particle diameter of the second resin particles is confined to 10-70 nm.

8. The method according to claim 1, wherein the organic component is novolac resin.

9. The method according to claim 8, wherein the first temperature is confined to 90-160° C.

10. The method according to claim 1, wherein the first resin particles and the second resin particles are formed of a material selected from the group consisting of polymethyl methacrylate, polystyrene and styrene-acryl copolymer.

11. The method according to claim 1, wherein the first resin particles are contained in the first slurry at a concentration of 0.01-10 wt % and the second resin particles are contained in the second slurry at a concentration of 0.01-10 wt %.

12. The method according to claim 1, wherein the water-soluble polymer is selected from the group consisting of methyl cellulose, methylhydroxyethyl cellulose, methylhydroxypropyl cellulose, hydroxyethyl cellulose, hydroxypropyl cellulose, carboxymethyl cellulose, carboxyethyl cellulose, carboxymethylhydroxyethyl cellulose, chitosan, polyethylene glycol, polyethylene imine, polyvinylpyrrolidone, polyvinyl alcohol, polyacrylic acid and salts thereof, polyacryl amide and polyethylene oxide.

13. The method according to claim 1, wherein an average molecular weight of the water-soluble polymer is confined to 500-1,000,000.

14. The method according to claim 1, wherein the water-soluble polymer is contained in the first slurry as well as in the second slurry at a concentration of 0.001-10 wt %.

15. The method according to claim 1, wherein the organic film precursor is formed having, on its surface, a stepped portion reflecting the recess.

16. A method for manufacturing a semiconductor device, comprising:
forming, through at least an organic insulating film, a first hard mask containing an inorganic material and a second hard mask containing an inorganic material, a third hard mask containing an inorganic material, above a semiconductor substrate;
forming a pattern of a wiring trench to be transcribed to the organic insulating film in the third hard mask, thereby exposing the second hard mask on a bottom of the pattern;
forming a coated film by applying a first solution containing a solvent and an organic component above the third hard mask where the pattern of the wiring trench is formed;
baking the coated film at a first temperature which does not accomplish cross-linking of the organic component to obtain an organic film precursor;
polishing the organic film precursor using a first slurry containing first resin particles having an average particle diameter ranging from 100-300 nm and a water-soluble polymer, thereby planarizing a surface of the organic film precursor;
polishing the organic film precursor where the surface is planarized using a second slurry containing second resin particles having an average particle diameter ranging from 10-70 nm and a water-soluble polymer, thereby leaving the organic film precursor in the wiring trench pattern and exposing the third hard mask;
applying a second solution containing a solvent and an organic component on the exposed surface of the third hard mask having the wiring trench pattern while leaving the organic film precursor in the wiring trench pattern, thereby forming an underlying film formed of an organic film;
forming an intermediate layer and a resist film successively above the underlying film; and
subjecting the resist film to patterning exposure.

17. The method according to claim 16, further comprising:
forming a pattern of a hole in the resist film;
transcribing the pattern of the hole to the organic insulating film to form a hole in the organic insulating film and, at the same time, removing the underlying film to create the pattern of the wiring trench;
transcribing the pattern of the wiring trench to the organic insulating film to form a wiring trench communicating with the hole; and
forming a dual damascene wiring in the hole and in the wiring trench.

18. The method according to claim 16, further comprising:
baking the organic film precursor left in the pattern of the wiring trench at a second temperature which is higher than the first temperature to remove the solvent before applying the second solution.

19. The method according to claim 16, wherein a quantity of the second resin particles existing in the second slurry is smaller than that of the first resin particles existing in the first slurry.

20. The method according to claim 16, wherein the second slurry contains a larger quantity of water-soluble polymer than that contained in the first slurry.
